(19) United States
(12) Patent Application Publication
(10) Pub. No.: US 2025/0048878 A1
(43) Pub. Date: Feb. 6, 2025

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventors: Lei Lv, Wuhan (CN); Meng Jin, Wuhan (CN); Tao Yuan, Wuhan (CN); Jinchang Huang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/296,234

(22) PCT Filed: Mar. 30, 2021
(86) PCT No.: PCT/CN2021/083814

§ 371 Date: May 28, 2024

(30) Foreign Application Priority Data
Mar. 9, 2021 (CN) 202110257751.1

(51) Int. Cl. H10K 59/65; H10K 59/12; H10K 59/122; H10K 59/35; H10K 59/80

(52) U.S. Cl. CPC H10K 59/65; H10K 59/1201; H10K 59/122; H10K 59/353; H10K 59/80524

(57) ABSTRACT

The present disclosure discloses a display panel and a manufacturing method thereof. The display panel includes a first display region and a third display region; the display panel includes a substrate and a suppression layer. A ratio of an area of an orthographic projection of a second cathode suppression layer on the substrate to an area of the third display region is less than a ratio of an area of an orthographic projection of a first cathode suppression layer on the substrate to an area of the first display region. The third display region provides transitional effect, and the suppression layer is configured to increase a light transmittance of the first display region and reduce a brightness difference of each display region.

### FIELD

The present disclosure relates to a field of display technology and in particular to a display panel and manufacturing method thereof.

### BACKGROUND

Organic light emitting diode (OLED) display technology has received more and more attention from scientific researchers, and is widely used in display fields such as mobile phones, flat panels, and TVs. With rapid development of display devices, users have increasingly higher demands for a screen-to-body ratio of display devices. Therefore, large-size and high-resolution comprehensive display devices have become a future development trend.

In prior art, in order to increase the screen-to-body ratio as much as possible, optical components such as a front camera and a facial recognition component are usually installed under a screen. However, in current OLED full-scale display equipment, a cathode is disposed by a whole surface method, and the cathode has poor light transmittance, which causes the optical components under the screen to fail to receive sufficient light of signals, which affects normal operation of the optical components.

Therefore, there is urgent need for a display panel and a manufacturing method thereof to solve the above-mentioned technical problems.

### SUMMARY

### Technical Problem

The embodiments of the present disclosure provide a display panel and a manufacturing method thereof, so as to solve the problem that an optical element disposed under a screen cannot receive sufficient light of signals, which affects normal operation of the optical element.

### Solution to Problem

### Technical Solution

In order to solve the above-mentioned problems, the technical solutions provided by the present disclosure are as follows:

One embodiment of the present disclosure provides a display panel, including a first display region, a second display region, and a third display region positioned between the first display region and the second display region, wherein the display panel further includes:
a substrate;
a pixel definition layer disposed on a side of the substrate, wherein a plurality of spaced-apart pixel openings are defined on the pixel definition layer, and a gap region is defined between two adjacent pixel openings; and
a suppression layer disposed on a side of the pixel definition layer away from the substrate, wherein the suppression layer is positioned in the gap region; and
wherein the suppression layer includes a first cathode suppression layer positioned in the first display region and a second cathode suppression layer positioned in the third display region, and a ratio of an area of an orthographic projection of the second cathode suppression layer on the substrate to an area of the third display region is less than a ratio of an area of the orthographic projection of the first cathode suppression layer on the substrate to an area of the first display region.

In one embodiment of the present disclosure, the ratio of the area of the orthographic projection of the second cathode suppression layer on the substrate to the area of the third display region is less than or equal to one half of the ratio of the area of the orthographic projection of the first cathode suppression layer on the substrate to the area of the first display region.

In one embodiment of the present disclosure, the first cathode suppression layer includes a plurality of spaced-apart first light-transmitting blocks, and the second cathode suppression layer includes a plurality of spaced-apart second light-transmitting blocks; and wherein an area of an orthographic projection of one of the second light-transmitting blocks on the substrate is less than an area of an orthographic projection of one of the first light-transmitting blocks on the substrate, or/and a number of the second light-transmitting blocks is less than a number of the first light-transmitting blocks.

In one embodiment of the present disclosure, the third display region includes a plurality of partitions disposed away from the first display region, the second cathode suppression layer comprises a plurality of split bodies, and the plurality of split bodies correspond to the plurality of partitions one by one; and wherein the plurality of split bodies includes the plurality of second light-transmitting blocks, and wherein the split body has a greater distance from the first display region, has a smaller area of an orthographic projection on the substrate.

In one embodiment of the present disclosure, the split body has a greater distance from the first display region, has a fewer of the second light-transmitting blocks.

In one embodiment of the present disclosure, the split body has a greater distance from the first display region, has a smaller area of an orthographic projection of the second light-transmitting blocks on the substrate.

In one embodiment of the present disclosure, the display panel further includes a cathode layer disposed on the side of the pixel definition layer away from the substrate, and the cathode layer covers the pixel opening and at least part of the suppression layer; and wherein a thickness of the cathode layer positioned on the suppression layer is less than a thickness of the cathode layer positioned on the pixel opening.

In one embodiment of the present disclosure, the cathode layer includes electrode portions in one-to-one correspondence with the pixel openings and an overlap portion connecting two adjacent ones of the electrode portions, wherein the overlap portion is positioned in the first display region and the third display region.

In one embodiment of the present disclosure, both the first display region and the third display region include a plurality of light-transmitting partitions, and each of the light-transmitting partitions is surrounded by the overlap portion and the pixel openings comprising a first pixel opening, a second pixel opening, a third pixel opening, and a fourth pixel opening; and wherein the second pixel opening is adjacent to the first pixel opening and positioned at a side of the first pixel opening along a first direction, and the third pixel opening is adjacent to the second pixel opening and positioned at a side of the second pixel opening along a second direction, the fourth pixel opening is adjacent to both the first pixel opening and the third pixel opening, one of the first light-transmitting blocks is disposed corresponding to one of the light-transmitting partitions in the first display region, and one of the second light-transmitting blocks is disposed corresponding to one of the light-transmitting partitions in the third display region.

In one embodiment of the present disclosure, a shape of the orthographic projection of one of the first light-transmitting blocks on the substrate is adapted to a shape of a corresponding one of the light-transmitting partition, and a shape of the orthographic projection of one of the second light-transmitting blocks on the substrate is adapted to a shape of a corresponding one of the light-transmitting partition.

In one embodiment of the present disclosure, a shape of a side of the orthographic projection of the first light-transmitting block and a shape of a side of the orthographic projection of the second light-transmitting block on the substrate are curves.

In one embodiment of the present disclosure, an orthographic projection of the suppression layer on the substrate is separated from an orthographic projection of the second display region on the substrate.

In one embodiment of the present disclosure, an orthographic projection of the suppression layer on the substrate is separated from an orthographic projection of an anode of a sub-pixel on the substrate.

The present disclosure further provides a method of manufacturing a display panel, wherein the display panel includes a first display region, a second display region, and a third display region positioned between the first display region and the second display region, and the method of manufacturing the display panel includes:
forming a pixel definition layer on a side of the substrate, wherein a plurality of spaced-apart pixel openings are defined on the pixel definition layer, and a gap region is defined between two adjacent pixel openings; and
forming a suppression layer on a side of the pixel definition layer away from the substrate, wherein the suppression layer is positioned in the gap region, and the suppression layer includes a first cathode suppression layer positioned in the first display region and a second cathode suppression layer positioned in the third display region; and
wherein a ratio of an area of an orthographic projection of the second cathode suppression layer on the substrate to an area of the third display region is less than a ratio of an area of the orthographic projection of the first cathode suppression layer on the substrate to an area of the first display region.

In one embodiment of the present disclosure, the ratio of the area of the orthographic projection of the second cathode suppression layer on the substrate to the area of the third display region is less than or equal to one half of the ratio of the area of the orthographic projection of the first cathode suppression layer on the substrate to the area of the first display region.

In one embodiment of the present disclosure, the first cathode suppression layer includes a plurality of spaced-apart first light-transmitting blocks, and the second cathode suppression layer includes a plurality of spaced-apart second light-transmitting blocks; and wherein an area of an orthographic projection of one of the second light-transmitting blocks on the substrate is less than an area of an orthographic projection of one of the first light-transmitting blocks on the substrate, or/and a number of the second light-transmitting blocks is less than a number of the first light-transmitting blocks.

In one embodiment of the present disclosure, the third display region includes a plurality of partitions disposed away from the first display region, the second cathode suppression layer includes a plurality of split bodies, and the plurality of split bodies correspond to the plurality of partitions one by one; and wherein one of the plurality of split bodies includes a plurality of the second light-transmitting blocks, and wherein the split body has a greater distance from the first display region, has a smaller area of an orthographic projection on the substrate.

In one embodiment of the present disclosure, the split body has a greater distance from the first display region, has a fewer of the second light-transmitting blocks.

In one embodiment of the present disclosure, an orthographic projection of the suppression layer on the substrate is separated from an orthographic projection of the second display region on the substrate.

In one embodiment of the present disclosure, an orthographic projection of the suppression layer on the substrate is separated from an orthographic projection of an anode of a sub-pixel on the substrate.

### Advantageous Effect of Present Disclosure

### Advantageous Effect

By providing the suppression layer that has poor adhesion to the cathode layer or even repels to the cathode layer, when the cathode layer is formed by a whole-surface evaporation process, the cathode layer deposited on the suppression layer is thinner or there is no cathode layer deposition on the suppression layer, so that the present disclosure can greatly improve a light transmittance of the first display region without changing a process of manufacturing the cathode layer. Therefore, the optical elements disposed in the first display region can receive sufficient light of signals, thereby improving the imaging effect of the optical element. At the same time, by setting a third display region providing transitional effect between the first display region and the second display region, and the third display region can also be displayed, the third display region will not affect an overall display of the display panel. At the same time, by setting an area of the suppression layer in the first display region and the second display region, under a premise that the suppression layer is configured to increase the light transmittance of the first display region, the suppression layer can be used to make a display brightness of the first display region greater than a display brightness of the second display region, and the display brightness of the second display region is greater than a display brightness of the third display region, thereby reducing a brightness difference between a boundary between the first display region and the third display region and a boundary between the second display region and the third display region, to improve the display effect.

### BRIEF DESCRIPTION OF DRAWINGS

### Description of Drawings

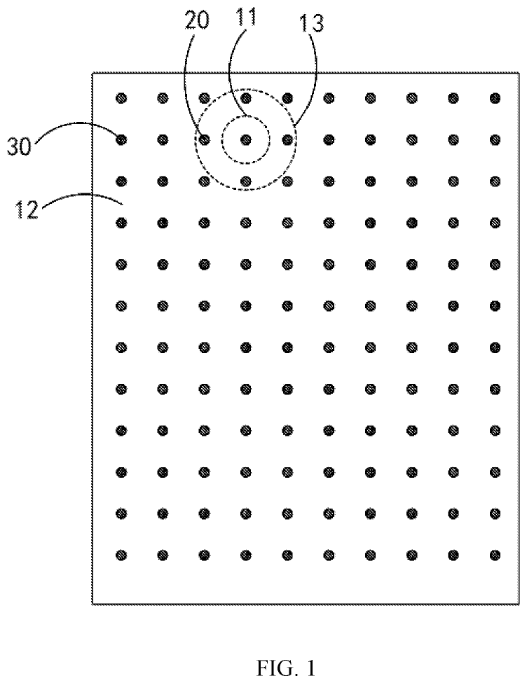

FIG. 1 is a schematic plan view of a display panel in one embodiment of the present disclosure.

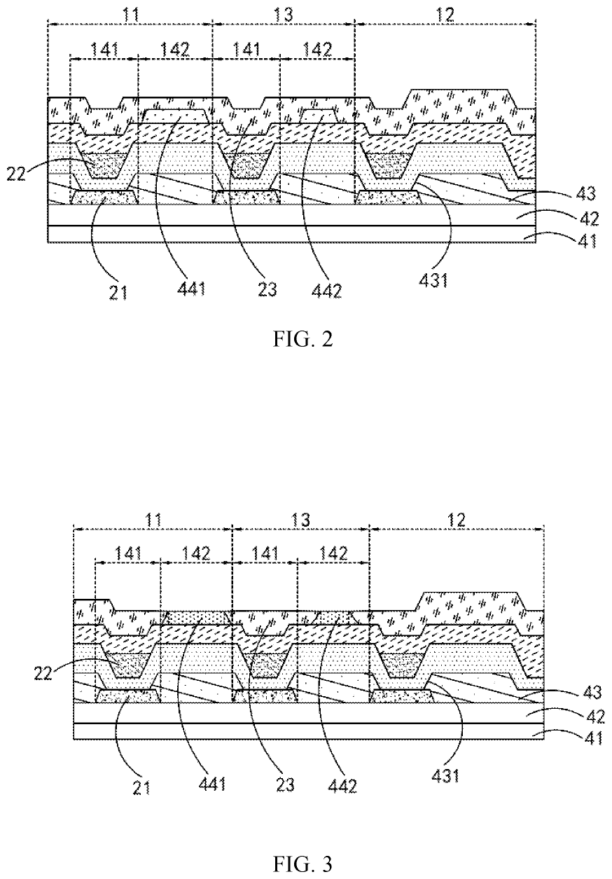

FIG. 2 is a schematic diagram of a structure of the display panel in one embodiment of the present disclosure.

FIG. 3 is a schematic diagram of a structure of the display panel in another embodiment of the present disclosure.

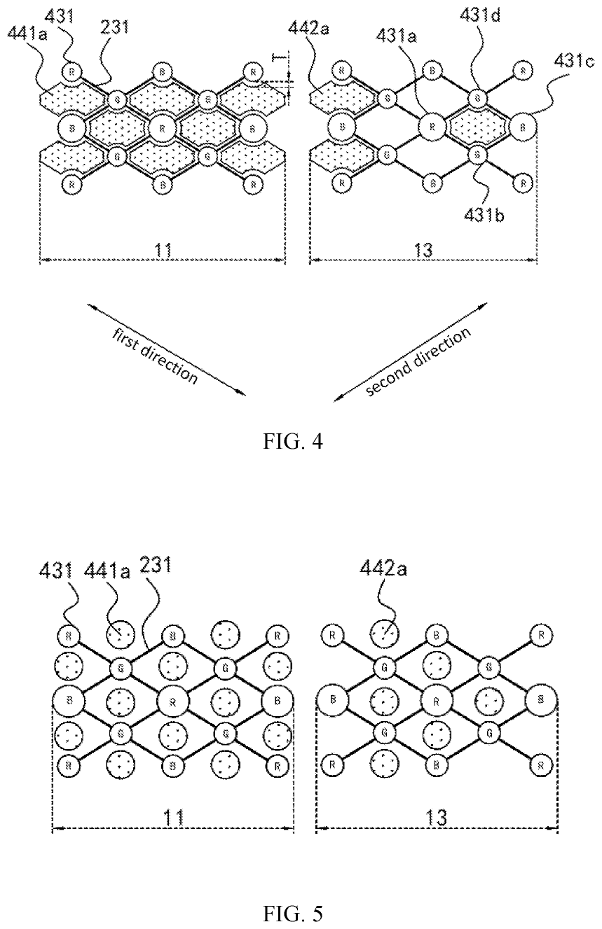

FIG. 4 is a schematic diagram of an arrangement of pixel openings and a first light-transmitting block and a second light-transmitting block in one embodiment of the present disclosure.

FIG. 5 is a schematic diagram of the arrangement of pixel openings and the first light-transmitting block and the second light-transmitting block in one embodiment of the present disclosure.

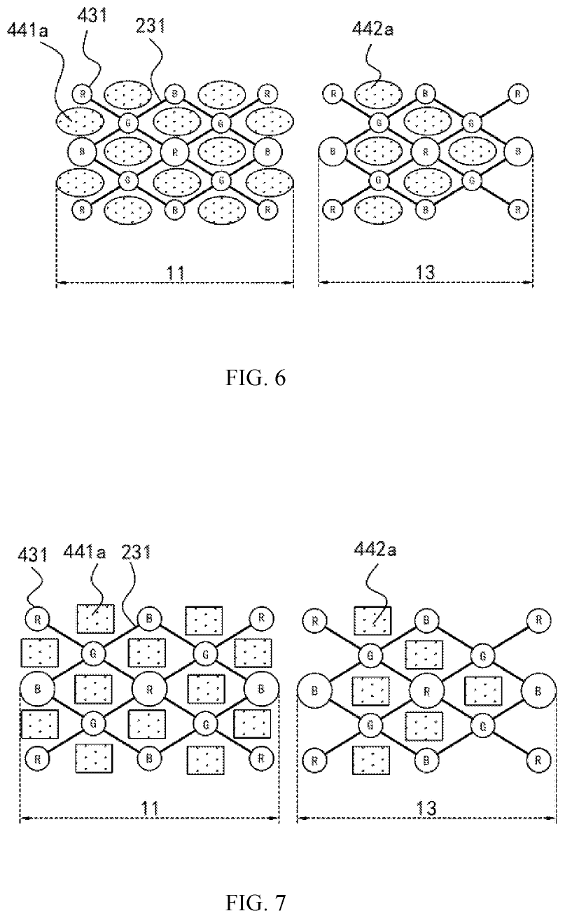

FIG. 6 is a schematic diagram of the arrangement of pixel openings and the first light-transmitting block and the second light-transmitting block in one embodiment of the present disclosure.

FIG. 7 is a schematic diagram of the arrangement of pixel openings and the first light-transmitting block and the second light-transmitting block in one embodiment of the present disclosure.

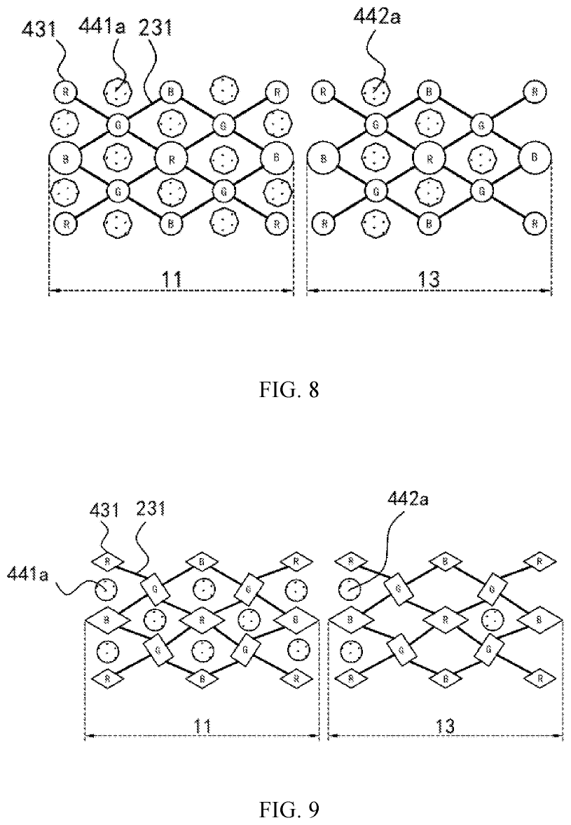

FIG. 8 is a schematic diagram of the arrangement of pixel openings and the first light-transmitting block and the second light-transmitting block in one embodiment of the present disclosure.

FIG. 9 is a schematic diagram of the arrangement of pixel openings and the first light-transmitting block and the second light-transmitting block in one embodiment of the present disclosure.

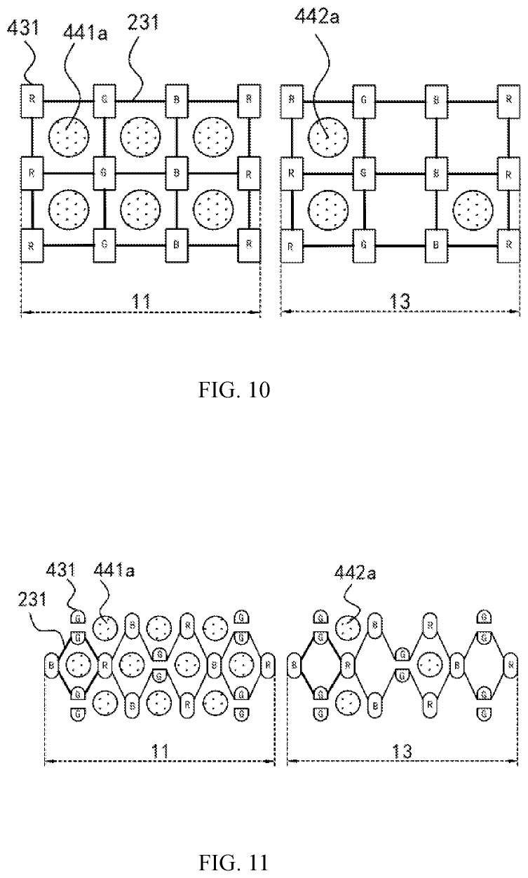

FIG. 10 is a schematic diagram of the arrangement of pixel openings and the first light-transmitting block and the second light-transmitting block in one embodiment of the present disclosure.

FIG. 11 is a schematic diagram of the arrangement of pixel openings and the first light-transmitting block and the second light-transmitting block in one embodiment of the present disclosure.

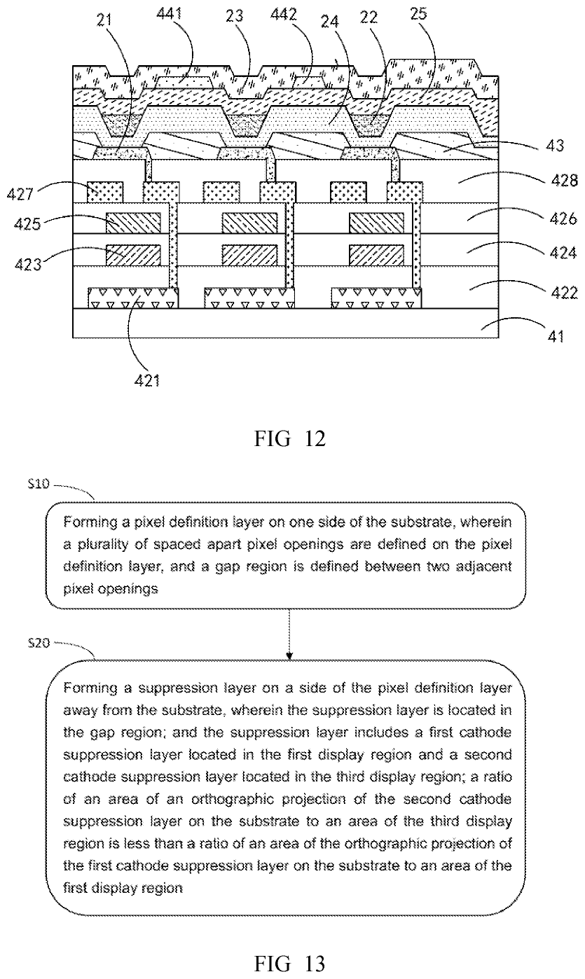

FIG. 12 is a schematic plan view of the display panel in one embodiment of the present disclosure.

FIG. 13 is a schematic diagram of manufacturing steps of the display panel in one embodiment of the present disclosure.

### DESCRIPTION OF REFERENCE SIGNS

11: first display region; 12: second display region; 13: third display region; 141: light-emitting region; 142: light-transmitting region; 20: first sub-pixel; 21: anode; 22: light-emitting layer; 23: cathode layer; 231: overlap portion; 24: first auxiliary layer; 25: second auxiliary layer; 30: second sub-pixel; 41: substrate; 42: array layer; 421: active layer; 422: first insulation layer; 423: first gate; 424: second insulation layer; 425: second gate; 426: interlayer dielectric layer; 427: source and drain metal layer; 428: planarization layer; 43: pixel definition layer; 431: pixel opening; 431a: first pixel opening; 431b: second pixel opening; 431c: third pixel opening; 431d: fourth pixel opening; 441: first cathode suppression layer; 441a: first light-transmitting block; 442: second cathode suppression layer; 442a: second light-transmitting block.

### EMBODIMENTS OF THE PRESENT DISCLOSURE

### Detailed Description of Preferred Embodiments

The present disclosure provides a display panel and a manufacturing method thereof. In order to make the objectives, technical solutions, and effects of the present disclosure more specific and clearer, the present disclosure will be further described in detail below with reference to the accompanying figures and embodiments. It should be understood that the specific embodiments described here are only used to explain the present disclosure, and are not used to limit the present disclosure.

The embodiment of the present disclosure provides a display panel and a manufacturing method thereof. Detailed descriptions are provided below. It should be understood that an order of description in the following embodiments is not meant to limit a preferred order of the embodiments.

One embodiment of the present disclosure provides a display panel. As shown in FIG. 1, the display panel includes a first display region 11, a second display region 12, and a third display region 13. The second display region 12 is adjacent to the first display region 11. The third display region 13 is positioned between the first display region 11 and the second display region 12, and the first display region 11 can be disposed at any position on the display panel.

The display panel is a full-screen display panel, a plurality of first sub-pixels 20 are disposed in the first display region 11 and the third display region 13, and a plurality of second sub-pixels 30 are disposed in the second display region 12.

It should be noted that the first display region 11 is a function additional region. The first display region 11 can be configured to display images, so that the display panel can present a full-screen display effect, and the first display region 11 can also be configured to install cameras, optical touch components, and optical components such as fingerprint recognition sensors to improve user experience. The second display region 12 is a main display region, and the second display region 12 is configured to display images; the third display region 13 is a transitional display region to alleviate a problem that a brightness difference between the first display region 11 and the second display region 12 causes the display effect to decrease.

It should also be noted that a pixel density of the first sub-pixels 20 in the first display region 11, a pixel density of the first sub-pixels 20 of the third display region 13, and a pixel density of the second sub-pixels 30 in the second display region 12 may be the same or different.

In one embodiment, a light transmittance of the first display region 11 is greater than a light transmittance of the second display region 12, and a light transmittance of the third display region 13 may be greater or less than the light transmittance of the first display region 11.

It can be understood that, for optical elements, the light transmittance of the first display region 11 has a great influence on an operation of the optical element, and the light transmittance of the first display region 11 is related to a film layer structure of the first display region 11. Taking the optical element as a camera for example, when the camera performs photography, the higher the light transmittance of the first display region 11, the better the imaging quality of the camera.

Specifically, as shown in FIGS. 2 and 3, the display panel includes a substrate 41, a pixel definition layer 43 disposed on a side of the substrate 41, and a cathode layer 23 disposed on a side of the pixel definition layer 43 away from the substrate 41. The pixel definition layer 43 is provided with a plurality of spaced-apart pixel openings 431, and a gap region is defined between two adjacent pixel openings 431.

The substrate 41 may be a flexible substrate 41, and a material of the flexible substrate 41 may be an organic material such as polyimide. The substrate 41 may also be a rigid substrate 41, and a material of the rigid substrate 41 may be, for example, glass, metal, plastic, etc. The substrate 41 can be a single-layer film structure or a multi-layer film structure.

In one embodiment of the present disclosure, the first display region 11 and the third display region 13 are provided with a suppression layer, and the suppression layer is made of a light-transmitting material, wherein the suppression layer is disposed on a side of the pixel definition layer 43 away from one the substrate, and the suppression layer is positioned in the gap region.

A cathode layer 23 covers the pixel opening 431 and at least part of the suppression layer, wherein a thickness of the cathode layer 23 positioned on the suppression layer is less than a thickness of the cathode layer positioned on the pixel opening 431.

It should be noted that by providing the suppression layer that has poor adhesion to the cathode layer 23 or even repels to the cathode layer, when the cathode layer 23 is formed by a whole-surface evaporation process, due to an adhesion between the cathode layer 23 and other film layers being greater than an adhesion between the cathode layer 23 and the suppression layer, the cathode layer 23 deposited on the suppression layer is thinner or there is no cathode layer 23 deposition on the suppression layer, so that the cathode layer 23 deposited on the gap region is thinner or there is no cathode layer 23 deposited on the gap region. Thereby the present disclosure can improve a light transmittance of the first display region 11 without changing a process of manufacturing the cathode layer 23. Therefore, the optical elements disposed in the first display region 11 can receive sufficient light of signals.

In one embodiment, as shown in FIG. 2, the thickness of the cathode layer 23 positioned on the suppression layer is greater than 0, that is, the thinner cathode layer 23 is deposited on the suppression layer.

In another embodiment, as shown in FIG. 3, the suppression layer includes a plurality of light-transmitting blocks, and the light-transmitting blocks include a platform portion and an edge portion positioned on an edge of the platform portion. A thickness of the cathode layer 23 positioned on the platform portion is 0, and the cathode layer 23 covers at least a part of the edge portion, that is, a thinner cathode layer is deposited only on the edge portion, and no cathode layer 23 is deposited on the platform portion.

In one embodiment, a material of the cathode layer 23 may be metallic magnesium, and a material of the suppression layer may be at least one of bis(2-methyl-8-hydroxyquinoline)-4-(p-phenylphenol) aluminum (BAlq), 3-(biphenyl-4-yl)-5-(4-tert-butylphenyl)-4-phenyl-4H-1,2,4-triazole (TAZ), or indium oxide (OTI). Adhesions of metallic magnesium to BAlq, TAZ and OTI materials are poor, when metallic magnesium is vapor-deposited to form the cathode layer 23, the suppression layer suppresses a formation of a film of metallic magnesium on the suppression layer.

In one embodiment of the present disclosure, the suppression layer includes a first cathode suppression layer 441 positioned in the first display region 11 and a second cathode suppression layer 442 positioned in the third display region 13.

A ratio of an area of an orthographic projection of the second cathode suppression layer 442 on the substrate 41 to an area of the third display region 13 is less than a ratio of an area of the orthographic projection of the first cathode suppression layer 441 on the substrate 41 to an area of the first display region 11.

It should be noted that, theoretically, the larger the area of the first cathode suppression layer 441, the greater the light transmittance of the first display region 11. However, when the first cathode suppression layer 441 is used to thin or even remove part of the cathode layer 23, this will cause a display brightness of the first display region 11 to increase significantly, leading to the display brightness of the first display region 11 to be greater than a display brightness of the second display region 12, which will cause the first display region 11 and the second display region 12 to have a large brightness difference at a boundary, which affects the display effect of the display panel.

It can be understood that providing a third display region 13 provides transitional effect between the first display region 11 and the second display region 12, and the third display region 13 can also be displayed without affecting the overall display of the display panel. At the same time, by setting the area of the first cathode suppression layer 441 and the second cathode suppression layer 442 in the first display region 11 and the second display region 12, on the premise that the first cathode suppression layer 441 is used to increase the light transmittance of the first display region 11, the display brightness of the first display region 11 can be greater than a display brightness of the second display region 12, and the display brightness of the third display region 13 is greater than a display brightness of the second display region 12, thereby reducing a brightness difference at a boundary between the first display region 11 and the third display region 13 and at a boundary between the second display region 12 and the third display region 13, and thereby improving the display effect.

In one embodiment, the ratio of the area of the orthographic projection of the second cathode suppression layer 442 on the substrate 41 to the area of the third display region 13 is less than or equal to one half of the ratio of the area of the orthographic projection of the first cathode suppression layer 441 on the substrate 41 to the area of the first display region 11, so that the third display region 13 can have a better transition of display brightness, which can further improve the brightness difference between the first display region 11 and the second display region 12.

In one embodiment, a thickness of the portion of the cathode layer 23 corresponding to the pixel opening 431 is greater than or equal to a thickness of the suppression layer, so as to prevent a large height difference between the cathode layer 23 and the suppression layer from affecting a setting of an encapsulation layer.

In this embodiment of the present disclosure, an area of the orthographic projection of the first cathode suppression layer 441 on the substrate 41 (hereinafter referred to as the “area of the first cathode suppression layer 441”) is less than or equal to 0.95 times the area of the first display region 11.

It can be understood that, theoretically, the larger the area of the first cathode suppression layer 441, the greater the light transmittance of the first display region 11. However, as a sufficient number of first sub-pixels 20 need to be provided in the first display region 11, and when the first cathode suppression layer 441 is used to thin or even remove the cathode layer 23 positioned in the first display region 11, thinning the cathode layer 23 will also cause a resistance of the cathode layer 23 to increase, this affects electrical properties of the cathode layer 23, thereby affecting the normal display of the first sub-pixels 20, so the setting area of the first cathode suppression layer 441 cannot be infinitely large. Under a premise that the first display region 11 can be displayed normally, by setting the area ratio of the first cathode suppression layer 441 to the first display region 11, the light transmittance of the first display region 11 can be increased as much as possible.

Further, the area of the orthographic projection of the first cathode suppression layer 441 on the substrate 41 is greater than or equal to 0.05 times the area of the first display region 11.

It should be noted that the smaller the area of the first cathode suppression layer 441, the less an impact on the electrical performance of the cathode layer 23 in the first display region 11 and the first sub-pixels 20. However, disposing the first cathode suppression layer 441 requires additional processes and materials, which will increase the manufacturing cost of the display panel. If the area of the first cathode suppression layer 441 is too small, the increase in the light transmittance of the first display region 11 will be decreased, which will reduce a cost-effectiveness of disposing the first cathode suppression layer 441.

In one embodiment, the first sub-pixels 20 are disposed on a side of the substrate 41; each of the first sub-pixel 20 includes an anode 21, a light-emitting layer 22, and the cathode layer 23; the light-emitting layer 22 is disposed on a side of the anode 21 away from the substrate 41, and the cathode layer 23 is disposed on a side of the light-emitting layer 22 away from the substrate 41.

Specifically, the display panel further includes an array layer 42 disposed on a side of the substrate 41.

The anode 21 is positioned on the side of the array layer 42 away from the substrate 41, and the pixel opening 431 exposes at least a part of the anode 21; the pixel definition layer 43 is provided on the array layer 42 and the substrate 41. The anode 21 is on the side away from the substrate 41, and the cathode 23 is disposed on the side of the pixel definition layer 43 away from the substrate 41.

Specifically, an orthographic projection of the suppression layer on the substrate 41 is separated from an orthographic projection of the anode 21 on the substrate 41, that is, an orthographic projection of the first cathode suppression layer 441 on the substrate 41 is separated from an orthographic projection of the anode 21 on the substrate 41, at the same time, an orthographic projection of the second cathode suppression layer 442 on the substrate 41 is separated from an orthographic projection of the anode 21 in the third display region 13 on the substrate 41.

It should be noted that the orthographic projection of the anode 21 on the substrate 41 will cover an orthographic projection of the pixel opening 431 on the substrate 41, and in order to ensure normal display of the first sub-pixels 20, it is necessary to ensure that an orthographic projection of the cathode layer 23 on the substrate 41 covers an orthographic projection of the pixel opening 431 on the substrate 41. By disposing the suppression layer and the anode 21 to not overlap, it can be ensured that the first light-transmitting block 441a and the second light-transmitting block 442a are kept at a certain distance from the pixel opening 431, while ensuring that an orthographic projection of the cathode layer 23 on the substrate 41 can cover an orthographic projection of the pixel openings 431 on the substrate 41, thereby prevent an disposing of the suppression layer from causing interference and adverse effects on the display of the first display region 11 and the third display region 13

In one embodiment, the orthographic projection of the suppression layer on the substrate 41 is separated from an orthographic projection of the second display region 12 on the substrate 41.

It can be understood that the suppression layer is only provided in the first display region 11 and the third display region 13, and the suppression layer is not provided in the second display region 12 to prevent the suppression layer from affecting the normal display of the second display region 12.

As shown in FIGS. 2 to 11, in one embodiment, the first cathode suppression layer 441 includes a plurality of spaced-apart first light-transmitting blocks 441a, and the second cathode suppression layer 442 includes a plurality of spaced-apart second light-transmitting blocks 442a.

An area of an orthographic projection of the second light-transmitting block 442a on the substrate 41 (hereinafter referred to as the “area of the second light-transmitting block 442a”) is smaller than an orthographic projection of the first light-transmitting block 441a on the substrate 41. A projected area (hereinafter referred to as the “area of the first light-transmitting block 441a”), or/and, a number of the second light-transmitting blocks 442a is less than a number of the first light-transmitting blocks 441a.

It can be understood that by setting the number of the second light-transmitting blocks 442a to be less than the number of the first light-transmitting blocks 441a, or/and, an area of a single second light-transmitting block 442a is smaller than an area of a single first light-transmitting block 441a, thus, an area of the second cathode suppression layer 442 is smaller than the area of the first cathode suppression layer 441.

It should be noted that the area of the orthographic projection of all the first light-transmitting blocks 441a on the substrate 41 may be the same or different, and the area of the orthographic projection of all the second light-transmitting blocks 442a on the substrate 41 may be the same or different. The area of the orthographic projection of the second light-transmitting block 442a on the substrate 41 is smaller than the area of the orthographic projection of the first light-transmitting block 441a on the substrate 41, which means that an area of largest one of the second light-transmitting blocks 442a is smaller than an area of the smallest one of the first light-transmitting block 441a.

In one embodiment, when the number of the second light-transmitting blocks 442a is less than the number of the first light-transmitting blocks 441a, the area of the orthographic projection of all the first light-transmitting blocks 441a on the substrate 41 is the same, the area of the orthographic projection of all the second light-transmitting blocks 442a on the substrate 41 is the same, and the area of the orthographic projection of the first light-transmitting block 441a on the substrate 41 is the same as the area of the orthographic projection of the second light-transmitting blocks 442a on the substrate 41.

Specifically, the third display region 13 includes a plurality of partitions disposed away from the first display region 11, and the second cathode suppression layer 442 includes a plurality of split bodies, and the plurality of split bodies correspond to the partitions one by one.

One of the plurality of split bodies includes a plurality of the second light-transmitting blocks 442a, and the greater a distance between the split body and the first display region 11, the smaller an area of an orthographic projection of the split body on the substrate 41 (hereinafter referred to as “an area of the split body”).

It can be understood that the greater the distance between the partition and the first display region 11, that is, the greater the distance between the split body set corresponding to the partition and the first display region 11, wherein each split body is composed of all the second light-transmitting blocks 442a positioned in the corresponding partition, and the split bodies of the first cathode suppression layer 441 in the third display region 13 are disposed in a gradual arrangement, the smaller the area of the split bodies, and the lesser the display brightness. Thereby, the display brightness of each subarea of the third display region 13 is gradually reduced from the first display region 11 to the second display region 12, so that the third display region 13 provides a better display brightness transition effect, and improves the display effect of the display panel.

It should be noted that the split body may be an integrally formed structure, that is, a plurality of second light-transmitting blocks 442a are connected to each other and integrally formed; all the second light-transmitting blocks 442a of each split body can also be disposed at intervals, and all the second light-transmitting blocks 442a of each split body can be disposed around the first display region 11.

In one embodiment, the greater the distance between the split body and the first display region 11, the fewer the second light-transmitting blocks 442a in the split body.

At this time, the areas of all the second light-transmitting blocks 442a in all the split bodies may be the same or different.

In one embodiment, the greater the distance between the split body with and the first display region 11, the smaller the area of the orthographic projection of the second light-transmitting block 442a on the substrate 41.

At this time, a number of all the second light-transmitting blocks 442a in all the split bodies may be the same or different.

It should be noted that by disposing the number or/and the area of the second light-transmitting blocks 442a, the area of the split body in each partition shows a gradual change.

Specifically, the cathode layer 23 includes electrode portions in one-to-one correspondence with the pixel openings 431 and an overlap portion 231 connecting two adjacent ones of the electrode portions, wherein the overlap portion 231 is positioned in the first display region 11 and the third display region 13, and two adjacent ones of the electrode portions are connected by the overlap portion 231.

It should be noted that the electrode portions are in one-to-one correspondence with the first sub-pixels 20, and the electrode portions are disposed dispersedly, that is, the first sub-pixels 20 are disposed dispersedly, which can prevent large area non-display or poor display during display due to display concentration, which is helpful to improve the user experience. At the same time, the overlap portion 231 is used to connect the electrode portion to reduce an overall resistance of the cathode layer 23, thereby reducing the current in the center area and an edge area of the first display region 11 caused by voltage drop. Therefore, uniformity of the display brightness of the first display region 11 can be improved.

In one embodiment, the overlap portion 231 and the electrode portion are positioned at different levels, and the overlap portion 231 and the electrode portion may be made of the same or different materials.

When the overlap portion 231 and the electrode part are made of different materials, the overlap portion 231 can be made of transparent conductive metal. At this time, when the cathode layer 23 is deposited by the whole-surface evaporation process, a part other than the cathode layer 23 and the anode 21 can be removed by the suppression layer, and only the part corresponding to the cathode layer 23 and the anode 21 will be retained, thereby greatly improving the light transmittance of the first display region 11, and at the same time using the overlap portion 231 to reduce the overall resistance of the cathode layer 23.

In one embodiment, the overlap portion 231 and the electrode portion are provided in the same layer, and the overlap portion 231 and the electrode portion may be made of the same or different materials.

When the overlap portion 231 and the electrode portion are made of different materials, the overlap portion 231 can be made of a transparent conductive metal to greatly increase the light transmittance of the first display region 11, while using the overlap portion 231 to reduce a resistance of the electrode.

When the overlap portion 231 and the electrode portion are made of the same material, the overlap portion 231 may be integrally formed with the electrode portion.

At this time, both between two adjacent first light-transmitting blocks 441a and between two adjacent second light-transmitting blocks 442a are provided with overlap region, wherein the overlap portion 231 is positioned in the overlap region.

It should be noted that when the cathode layer 23 of all the sub-pixels is formed by vapor deposition on the entire surface, the cathode material is simultaneously deposited in the overlap regions between two adjacent first light-transmitting blocks 441a and between two adjacent second light-transmitting blocks 442a, to simultaneously form the electrode portion and the overlap portion 231 connecting the electrode portion, so that the overall resistance of the cathode layer 23 can be reduced without increasing the manufacturing process.

Specifically, the first display region 11 and the third display region 13 both include a light-emitting region 141 and a light-transmitting region 142. The light-emitting region 141 is used for emitting light for display, and the light-transmitting region 142 is used for transmitting external light to increase the light transmittance of the first display region 11 and the third display region 13.

An anode 21 of the first sub-pixel 20 is positioned in the light-emitting region 141, and the first light-transmitting block 441a and the second light-transmitting block 442a are positioned in the light-transmitting region 142.

It can be understood that by concentratedly disposing the suppression layer in the light-transmitting region 142, and by disposing the area of the first cathode suppression layer 441 and the second cathode suppression layer 442 of the suppression layer, an effect that the light transmittance of the first display region 11 is greater than the light transmittance of the third display region 13, and the light transmittance of the third display region 13 is greater than the light transmittance of the second display region 12 can be achieved.

In one embodiment, both the first display region 11 and the third display region 13 include a plurality of light-transmitting partitions, and each of the light-transmitting partitions is surrounded by the overlap portion 231 and the pixel openings including a first pixel opening 431a, a second pixel opening 431b, a third pixel opening 431c, and a fourth pixel opening 431d.

The second pixel opening 431b is adjacent to the first pixel opening 431a and positioned at a side of the first pixel opening 431a along a first direction, and the third pixel opening 431c is adjacent to the second pixel opening 431b and positioned at a side of the second pixel opening 431b along a second direction, the fourth pixel opening 431d is adjacent to both the first pixel opening 431a and the third pixel opening 431c.

It should be noted that, referring to FIG. 4, each light-transmitting partition is surrounded by four adjacent pixel openings 431 and the overlap portion 231.

It should also be noted that the first direction and the second direction are different directions, that is, the first direction crosses the second direction. As shown in FIG. 4, in FIG. 4, the first direction is parallel to the first pixel opening 431a. The first direction is parallel to a length direction of the overlap portion 231 between the first pixel opening 431a and the second pixel opening 431b, the second direction is parallel to the length direction of the overlap portion 231 between the second pixel opening 431b and the third pixel opening 431c.

It can be understood that by designing the positions of the pixel opening 431 and the first light-transmitting block 441a and the second light-transmitting block 442a to make a distribution of the first sub-pixels 20 and the first light-transmitting blocks 441a in the first display region 11 more even, an overall uniformity of display brightness and light transmittance of the first display region 11 can be ensured.

In one embodiment, one of the first light-transmitting blocks 441a is disposed corresponding to one of the light-transmitting partitions in the first display region, and one of the second light-transmitting blocks 442a is disposed corresponding to one of the light-transmitting partitions in the third display region to make a distribution of the first light-transmitting blocks 441a and the second light-transmitting blocks 442a more uniform, thereby improving uniformity of the display brightness of the first display region 11 and the third display region 13.

The first light-transmitting blocks 441a in the first display region 11 can be set in one-to-one correspondence with the light-transmitting partitions, and the second light-transmitting blocks 442a in the second display region 12 are positioned in a part of the light-transmitting partition.

It can be understood that each light-transmitting partition in the first display region 11 is correspondingly provided with a first light-transmitting block 441a, thereby increasing an area of the first cathode suppression layer 441 in the first display region 11, and greatly improving a light transmittance of the first display region 11, and only part of the light-transmitting partitions in the third display region 13 are provided with the second light-transmitting blocks 442a, so that an area of the second cathode suppression layer 442 of the suppression layer in the third display region 13 can be reduced by reducing a number of the second light-transmitting blocks 442a.

In one embodiment, in the four pixel openings 431 enclosed to form light-transmitting partitions, each of the pixel opening 431 corresponds to one of the first sub-pixels 20. The four first sub-pixels 20 correspond to the four pixel openings 431 surrounded forming the light-transmitting partition. The four first sub-pixels 20 include at least one red sub-pixel (“R” sub-pixel), one green sub-pixel (“G” sub-pixel), and one blue sub-pixel (“B” sub-pixel).

In one embodiment, as shown in FIG. 4, a shape of the orthographic projection of one of the first light-transmitting blocks 441a on the substrate is adapted to a shape of a corresponding one of the light-transmitting partition, and a shape of the orthographic projection of one of the second light-transmitting blocks 442a on the substrate is adapted to a shape of a corresponding one of the light-transmitting partition, so that under a premise that an area of the light-transmitting partition remains the same, a settable area of the first light-transmitting block 441a and the second light-transmitting block 442a is increased, further improving the light transmittance of the first display region 11 and the third display region 13.

In one embodiment, as shown in FIGS. 5 and 6, a shape of a side of the orthographic projection of the first light-transmitting block 441a and a shape of a side of the orthographic projection of the second light-transmitting block 442a on the substrate 41 are curves, overall shapes of the first light-transmitting block 441a and the second light-transmitting block 442a can be circular (FIG. 5), semicircular, elliptical (FIG. 6), or semi-elliptical equilateral, etc. which sides are curves.

It can be understood that in a manufacturing process of the suppression layer, a shape of the first light-transmitting block 441a and a shape of the second light-transmitting block 442a depend on a shape of the openings on the mask used in patterning. The shape and accuracy of the opening depends on the accuracy of the process and processing equipment. More advanced curve control process means better processing accuracy, therefore, the shape accuracies of finally formed first light-transmitting block 441a and the second light-transmitting block 442a are better, to prevent the finally formed first light-transmitting block 441a and the second light-transmitting block 442a from falling into the pixel opening 431 and affecting the normal display of the first sub-pixels 20, so as to improve the manufacturing yield of the display panel.

As shown in FIGS. 7 and 8, the shape of the first light-transmitting block 441a and the second light-transmitting block 442a can also be regular or irregular shapes such as square (FIG. 7), octagonal (FIG. 8), or triangular.

It should be noted that a shape of the pixel opening 431 matches a shape of the first sub-pixel 20. FIGS. 4 to 8 only illustrate the situation where the shape of the pixel opening 431 is circular. In one embodiment, as shown in FIGS. 9 to 11, the shape of the pixel opening 431 can also be prismatic (FIG. 9), square (FIG. 10), or oval (FIG. 11), etc. The shape of all the pixel openings 431 can be the same or different.

It should also be noted that FIGS. 4 to 11 only illustrate the situation where the shape and size of the first light-transmitting block 441a and the second light-transmitting block 442a are the same. In one embodiment, the shapes of the first light-transmitting block 441a and the second light-transmitting block 442a may be different or partially different, the size of the first light-transmitting block 441a and the second light-transmitting block 442a may be different or partly different.

It can be understood that the shape of the overlap portion 231 in FIGS. 4 to 11 is only for illustration, the shape of the overlap portion 231 can be adapted to the shape of the overlap region, and the overlap portion 231 is distributed throughout the overlap region.

As shown in FIG. 12, in one embodiment, the light-emitting layer 22 is an organic light-emitting material layer, and the display panel further includes a first auxiliary layer 24 positioned on a side of the anode 21 away from the substrate 41, and the second auxiliary layer 25 positioned on a side of the first auxiliary layer 24 away from the substrate 41.

The light-emitting layer 22 is positioned between the first auxiliary layer 24 and the second auxiliary layer 25, the light-emitting layer 22 is positioned in the pixel opening 431, and a portion of the first auxiliary layer 24 is positioned in the pixel definition layer 43 and covers a portion of the anode 21 positioned in the pixel opening 431.

The first auxiliary layer 24 may include a hole injection layer and a hole transport layer that are sequentially stacked in a direction away from the substrate 41, wherein the hole injection layer covers the anode 21; the second auxiliary layer 25 may include an electron transport layer and an electron injection layer sequentially stacked in a direction away from the substrate 41, wherein the electron transport layer covers the light-emitting layer 22.

In one embodiment of the present disclosure, the manufacturing materials of the first auxiliary layer 24 and the second auxiliary layer 25 are transparent materials, which have less influence on the light transmittance of the first display region 11. Therefore, the auxiliary layer 24 and the second auxiliary layer 25 may cover the light-emitting region 141 and the light-transmitting region 142.

It can be understood that, at this time, the cathode layer 23 and the suppression layer are disposed on a side of the second auxiliary layer 25 away from the substrate 41. An adhesive force of the cathode layer 23 and the second auxiliary layer 25 is greater than an adhesive force of the cathode layer 23 and the suppression layer. A thickness of the portion of the cathode layer 23 on the second auxiliary layer 25 is greater than a thickness of the portion of the cathode layer 23 on the suppression layer

In one embodiment, the light-emitting layer 22 is only positioned in the light-emitting region 141, and the light-emitting layer 22 is not provided in the light-transmitting region 142, which can prevent the light-emitting layer 22 from affecting the light transmittance of the light-transmitting region 142, which helps to improve the light transmittance of the first display region 11.

In one embodiment, the array layer 42 includes an active layer 421 disposed on the substrate 41, a first insulation layer 422 covering the active layer 421, a first gate 423 disposed on a side of the first insulation layer 422 away from the active layer 421, a second insulation layer 424 covering the first gate 423, a second gate 425 disposed on a side of the second insulation layer 424 away from the substrate 41, an interlayer dielectric layer 426 covering the second gate 425, a source and drain metal layer 427 disposed on a side of the interlayer dielectric layer 426 away from the substrate 41, and a planarization layer 428 covering the source and drain metal layer 427.

The anode 21 and the pixel definition layer 43 are disposed on the side of the planarization layer 428 away from the substrate 41, the source and drain metal layer 427 includes a source electrode and a drain electrode, and the anode 21 is in contact with one of the source electrode or the drain electrode by a through hole.

Based on the above-mentioned display panel, the present disclosure also provides a method of manufacturing the display panel. The display panel includes a first display region 11, a second display region 12 disposed around at least part of the first display region 11, and a third display region 13 positioned between the first display region 11 and the second display region 12.

Specifically, as shown in FIG. 13, the method of manufacturing the display panel includes:

S10: Forming a pixel definition layer 43 on a side of the substrate 41, wherein a plurality of spaced-apart pixel openings 431 are defined on the pixel definition layer 43, and a gap region is defined between two adjacent pixel openings 431.

S20: Forming a suppression layer on a side of the pixel definition layer 43 away from the substrate 41, wherein the suppression layer is positioned in the gap region; and the suppression layer includes a first cathode suppression layer 441 positioned in the first display region 11 and a second cathode suppression layer 442 positioned in the third display region 13; a ratio of an area of an orthographic projection of the second cathode suppression layer 442 on the substrate 41 to an area of the third display region 13 is less than a ratio of an area of the orthographic projection of the first cathode suppression layer 441 on the substrate 41 to an area of the first display region 11.

In the embodiments of the present disclosure, a specific structure of the display panel can be referred to any of the above-mentioned embodiments and figures of the display panel, which will not be repeated here.

It can be understood that, for those of ordinary skill in the art, equivalent replacements or changes can be made according to the technical solution of the present disclosure and its inventive concept, and all these changes or replacements shall fall within a protection scope of the appended claims of the present disclosure.

1. A display panel, comprising a first display region, a second display region, and a third display region positioned between the first display region and the second display region, wherein the display panel further comprises:
a substrate;
a pixel definition layer disposed on a side of the substrate, wherein a plurality of spaced-apart pixel openings are defined on the pixel definition layer, and a gap region is defined between two adjacent pixel openings; and
a suppression layer disposed on a side of the pixel definition layer away from the substrate, wherein the suppression layer is positioned in the gap region; and
wherein the suppression layer comprises a first cathode suppression layer positioned in the first display region and a second cathode suppression layer positioned in the third display region, and a ratio of an area of an orthographic projection of the second cathode suppression layer on the substrate to an area of the third display region is less than a ratio of an area of an orthographic projection of the first cathode suppression layer on the substrate to an area of the first display region.

2. The display panel according to claim 1, wherein the ratio of the area of the orthographic projection of the second cathode suppression layer on the substrate to the area of the third display region is less than or equal to one half of the ratio of the area of the orthographic projection of the first cathode suppression layer on the substrate to the area of the first display region.

3. The display panel according to claim 1, wherein the first cathode suppression layer comprises a plurality of spaced-apart first light-transmitting blocks, and the second cathode suppression layer comprises a plurality of spaced-apart second light-transmitting blocks; and
wherein an area of an orthographic projection of one of the second light-transmitting blocks on the substrate is less than an area of an orthographic projection of one of the first light-transmitting blocks on the substrate, or/and a number of the second light-transmitting blocks is less than a number of the first light-transmitting blocks.

4. The display panel according to claim 3, wherein the third display region comprises a plurality of partitions disposed away from the first display region, the second cathode suppression layer comprises a plurality of split bodies, and the plurality of split bodies correspond to the plurality of partitions one by one; and
wherein one of the plurality of split bodies comprises a plurality of the second light-transmitting blocks, and wherein the split body has a greater distance from the first display region, has a smaller area of an orthographic projection on the substrate.

5. The display panel according to claim 4, wherein the split body has a greater distance from the first display region, has a fewer of the second light-transmitting blocks.

6. The display panel according to claim 5, wherein the split body has a greater distance from the first display region, has a smaller area of an orthographic projection of the second light-transmitting blocks on the substrate.

7. The display panel according to claim 3, wherein the display panel further comprises a cathode layer disposed on the side of the pixel definition layer away from the substrate, and the cathode layer covers the pixel openings and at least part of the suppression layer; and
wherein a thickness of the cathode layer positioned on the suppression layer is less than a thickness of the cathode layer positioned on the pixel openings.

8. The display panel according to claim 7, wherein the cathode layer comprises electrode portions in one-to-one correspondence with the pixel openings and an overlap portion connecting two adjacent ones of the electrode portions, wherein the overlap portion is positioned in the first display region and the third display region.

9. The display panel according to claim 8, wherein both the first display region and the third display region comprise a plurality of light-transmitting partitions, and each of the light-transmitting partitions is surrounded by the overlap portion and the pixel openings comprising a first pixel opening, a second pixel opening, a third pixel opening, and a fourth pixel opening; and
wherein the second pixel opening is adjacent to the first pixel opening and positioned at a side of the first pixel opening along a first direction, and the third pixel opening is adjacent to the second pixel opening and positioned at a side of the second pixel opening along a second direction, the fourth pixel opening is adjacent to both the first pixel opening and the third pixel opening, one of the first light-transmitting blocks is disposed corresponding to one of the light-transmitting partitions in the first display region, and one of the second light-transmitting blocks is disposed corresponding to one of the light-transmitting partitions in the third display region.

10. The display panel according to claim 9, wherein a shape of the orthographic projection of one of the first light-transmitting blocks on the substrate is adapted to a shape of a corresponding one of the light-transmitting partitions, and a shape of the orthographic projection of one of the second light-transmitting blocks on the substrate is adapted to a shape of a corresponding one of the light-transmitting partitions.

11. The display panel according to claim 9, wherein a shape of a side of the orthographic projection of the first light-transmitting block and a shape of a side of the orthographic projection of the second light-transmitting block on the substrate are curves.

12. The display panel according to claim 1, wherein an orthographic projection of the suppression layer on the substrate is separated from an orthographic projection of the second display region on the substrate.

13. The display panel according to claim 1, wherein an orthographic projection of the suppression layer on the substrate is separated from an orthographic projection of an anode of a sub-pixel on the substrate.

14. A method of manufacturing a display panel, wherein the display panel comprises a first display region, a second display region, and a third display region positioned between the first display region and the second display region, and the method of manufacturing the display panel comprises:
forming a pixel definition layer on a side of the substrate, wherein a plurality of spaced-apart pixel openings are defined on the pixel definition layer, and a gap region is defined between two adjacent pixel openings; and
forming a suppression layer on a side of the pixel definition layer away from the substrate, wherein the suppression layer is positioned in the gap region, and the suppression layer comprises a first cathode suppression layer positioned in the first display region and a second cathode suppression layer positioned in the third display region; and
wherein a ratio of an area of an orthographic projection of the second cathode suppression layer on the substrate to an area of the third display region is less than a ratio of an area of an orthographic projection of the first cathode suppression layer on the substrate to an area of the first display region.

15. The method of manufacturing the display panel according to claim 14, wherein the ratio of the area of the orthographic projection of the second cathode suppression layer on the substrate to the area of the third display region is less than or equal to one half of the ratio of the area of the orthographic projection of the first cathode suppression layer on the substrate to the area of the first display region.

16. The method of manufacturing the display panel according to claim 14, wherein the first cathode suppression layer comprises a plurality of spaced-apart first light-transmitting blocks, and the second cathode suppression layer comprises a plurality of spaced-apart second light-transmitting blocks; and
wherein an area of an orthographic projection of one of the second light-transmitting blocks on the substrate is less than an area of an orthographic projection of one of the first light-transmitting blocks on the substrate, or/and a number of the second light-transmitting blocks is less than a number of the first light-transmitting blocks.

17. The method of manufacturing the display panel according to claim 16, wherein the third display region comprises a plurality of partitions disposed away from the first display region, the second cathode suppression layer comprises a plurality of split bodies, and the plurality of split bodies corresponds to the plurality of partitions one by one; and
wherein one of the plurality of split bodies comprises a plurality of the second light-transmitting blocks, and wherein the split body has a greater distance from the first display region, has a smaller area of an orthographic projection on the substrate.

18. The manufacturing method of the display panel according to claim 17, wherein the split body has a greater distance from the first display region, has a fewer of the second light-transmitting blocks.

19. The manufacturing method of the display panel according to claim 14, wherein an orthographic projection of the suppression layer on the substrate is separated from an orthographic projection of the second display region on the substrate.

20. The manufacturing method of the display panel according to claim 14, wherein an orthographic projection of the suppression layer on the substrate is separated from an orthographic projection of an anode of a sub-pixel on the substrate.
